(19) United States
(12) Patent Application Publication
(10) Pub. No.: US 2026/0235964 A1
(43) Pub. Date: Aug. 13, 2026

(54) METROLOGY TOOL FOR OPHTHALMIC DEVICE PERFORMANCE ASSESSMENT

(71) Applicant: Alcon Inc., Fribourg (CH)

(72) Inventors: Christopher Paul Voita, Dove Canyon, CA (US); Federico Pennacchini, Irvine, CA (US); Richard J. Michaels, Irvine, CA (US)

(21) Appl. No.: 19/536,326

(22) Filed: Feb. 11, 2026

Related U.S. Application Data
(60) Provisional application No. 63/757,474, filed on Feb. 12, 2025.

(51) Int. Cl. G03F 7/00

(52) U.S. Cl. CPC G03F 7/705; G03F 7/70633; G03F 7/70641; G03F 7/70683

(57) ABSTRACT

A fabrication fixture assembly includes a base having at least one projection and a latitudinal positioning portion having at least one rail defining an arcuate slot extending therethrough. The arcuate slot follows a radius of curvature and the at least one projection is coupled to the latitudinal positioning portion through the at least one rail. The assembly also includes a rotational positioning portion attached to the at least one rail and moveable with the latitudinal positioning portion. The rotational positioning portion is configured to accept a metrology tool and selectively position the metrology tool in one of a plurality of rotational positions.

### BACKGROUND

The present disclosure relates to metrology tools, and more particularly, to a metrology tool for measuring and assessing the performance of an ophthalmic device.

The field of ophthalmology relies heavily on precise optical instruments for diagnosis, treatment, and surgical procedures. Ophthalmic devices, such as surgical microscopes, require precision design, fabrication, and alignment to ensure their accuracy and reliability in clinical settings. The periodic measurement of these instruments is crucial to assess performance as deviations can impact a user’s ability to visualize portions of the eye.

### SUMMARY

Disclosed herein is a fabrication fixture assembly. The assembly includes a base having at least one projection and a latitudinal positioning portion having at least one rail defining an arcuate slot extending therethrough. The arcuate slot follows a radius of curvature and the at least one projection is coupled to the latitudinal positioning portion through the at least one rail. The assembly also includes a rotational positioning portion attached to the at least one rail and moveable with the latitudinal positioning portion. The rotational positioning portion is configured to accept a metrology tool and selectively position the metrology tool in one of a plurality of rotational positions.

In one aspect of the disclosure the assembly includes the metrology tool attached to the rotational positioning portion for rotating the metrology tool between a plurality of rotational positions, wherein a portion of the metrology tool defines a hemispherical surface.

In one aspect of the disclosure wherein the at least one projection attached relative to the base includes a bearing.

In one aspect of the disclosure a center point is located at a center of a radius of curvature of the hemispherical surface.

In one aspect of the disclosure the assembly includes a detent configured to engage one of a plurality of recesses on at least one rail to secure the at least one rail in one of a plurality of positions relative to the base.

In one aspect of the disclosure the rotational positioning portion is fixed relative to the at least one rail.

In one aspect of the disclosure the metrology tool includes a plurality of markings at a plurality of latitudes and rotational positions along a hemispherical surface.

In one aspect of the disclosure the plurality of marking includes a set of markings with each marking in the set having a different resolution.

In one aspect of the disclosure the rotational positioning portion includes a gear drive unit and a detent for securing the metrology tool into one of a plurality of rotational positions.

In one aspect of the disclosure the metrology tool includes a projection configured to engage the rotational positioning portion of the fabrication fixture.

Disclosed herein is a method of operating a fabrication fixture to form markings on a metrology tool. The method includes inserting a metrology tool into the fabrication fixture with the metrology tool having a hemispherical surface with a center point and a pole. The method also includes positioning the metrology tool into a predetermined rotational and latitudinal positions. The metrology tool is positioned into each of the predetermined rotational and latitudinal positions with a rotational positioning portion and a latitudinal positioning portion on the fabrication fixture. The rotational positioning portion is configured to rotate the metrology tool about a rotational axis extending through the center point and the pole. The method also includes forming at least one marking at each of the predetermined rotational and latitudinal positions on the hemispherical surface of the metrology tool.

In one aspect of the disclosure the at least one marking includes a set of markings with each marking in the set of markings having a different resolution.

In one aspect of the disclosure the at least one marking includes a plurality of horizontal marks and a plurality of vertical marks.

In one aspect of the disclosure forming the at least one marking includes directing a laser beam through the center point and into engagement with the hemispherical surface.

In one aspect of the disclosure the center point of the hemispherical surface remains in a fixed location for each of the plurality of predetermined rotational and latitudinal positions.

Disclosed herein is an optical metrology tool assembly. The assembly includes a metrology tool having a hemispherical surface with a center point and a pole and a shaft extending from the metrology tool on an opposite side of the metrology tool from the hemispherical surface. The assembly also includes an optical assembly located adjacent to an attachment surface on the metrology tool. The optical assembly includes a cylindrical body portion having a diameter equal to twice a radial distance from the center point to the hemispherical surface with the cylindrical body includes a mating surface for engaging a distal

end of the metrology tool and the cylindrical body portion defining a central opening. The optical assembly also includes at least one lens located within the central opening and fixed relative to the cylindrical body portion.

In one aspect of the disclosure the optical assembly includes at least one entry port on a top flat surface for insertion of endoilluminator / chandelier illumination sources.

In one aspect of the disclosure the assembly includes a plurality of markings located at least of a plurality of latitudes on the hemispherical surface.

In one aspect of the disclosure the plurality of marking at each of the latitudes include a set of markings having different resolutions.

In one aspect of the disclosure the hemispherical surface is anodized and the plurality of markings are either recessed via laser material removal into the hemispherical surface or laser marked surface color changes without material removal.

### BRIEF DESCRIPTION OF THE DRAWINGS

The accompanying drawings, which are incorporated into and constitute a part of this specification, illustrate implementations of the disclosure and together with the description, explain the principles of the disclosure.

FIG. 1 schematically illustrates a perspective view of an example metrology tool in a fabrication fixture.

FIG. 2 schematically illustrates a side view of the example metrology tool in the fabrication fixture tool of FIG. 1.

FIG. 3 schematically illustrates a perspective view of an example hemispherical surface of the metrology tool of FIG. 1.

FIG. 4 schematically illustrates a top view of the example hemispherical metrology tool of FIG. 3.

FIG. 5 schematically illustrates a lens assembly connected to the metrology tool of FIG. 1 used in combination with a light source, WAVS, and an ophthalmic microscope.

FIG. 6 illustrates a method of fabricating markings on the hemispherical target portion of the metrology tool of FIG. 1.

FIG. 7 schematically illustrates an example marking on the hemispherical target portion of the metrology tool of FIG. 1.

### DETAILED DESCRIPTION

Those having ordinary skill in the art will recognize that terms such as “above,” “below”, “upward”, “downward”, “top”, “bottom”, “left”, “right”, etc., are used descriptively for the figures, and do not represent limitations on the scope of the disclosure, as defined by the appended claims. Furthermore, the teachings may be described herein in terms of functional and/or logical block components and/or various processing steps.

Assessing the quantitative optical performance of a Wide Angle Viewing System (WAVS) for an ophthalmic microscope can be difficult due to a lack of a standardized subjective/quantitative resolution testing tool that simulates the approximate total optical power and spherical retina geometry of a human eye positioned below a WAVS mounted to the ophthalmic microscope. One feature of this disclosure is to provide a fabrication fixture that allows for the creation of a device or metrology tool that allows for a quantitative measurement of optical performance for the WAVS. In particular, the metrology tool in this disclosure can determine optical performance between WAVS from different manufactures to improve comparison between the systems.

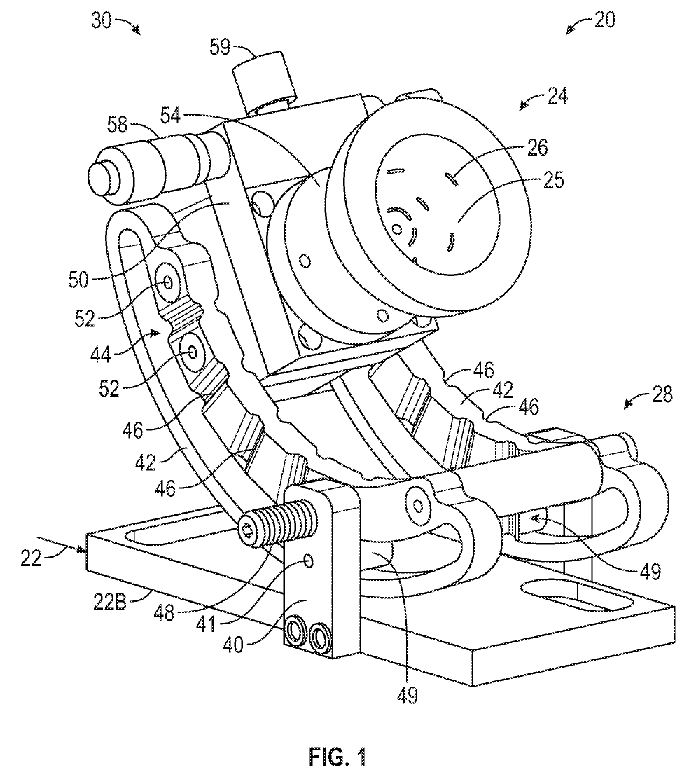

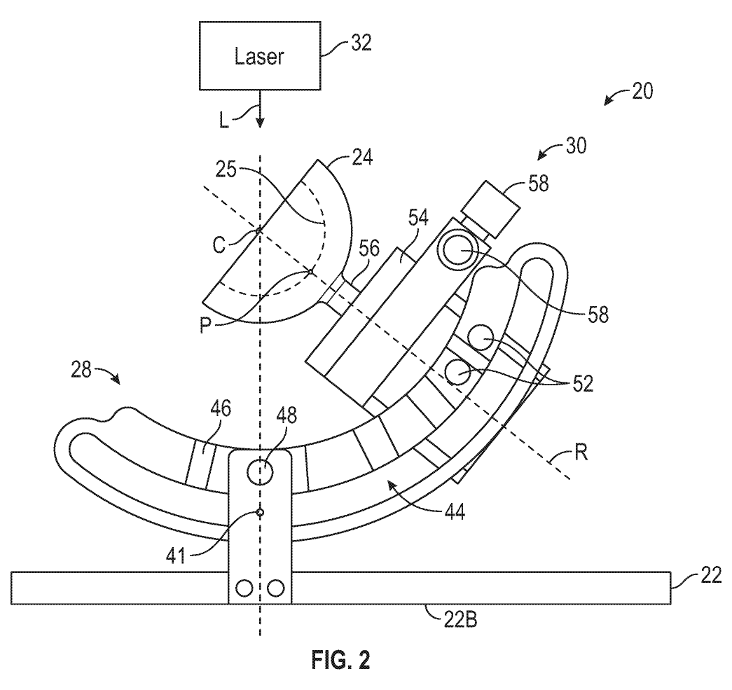

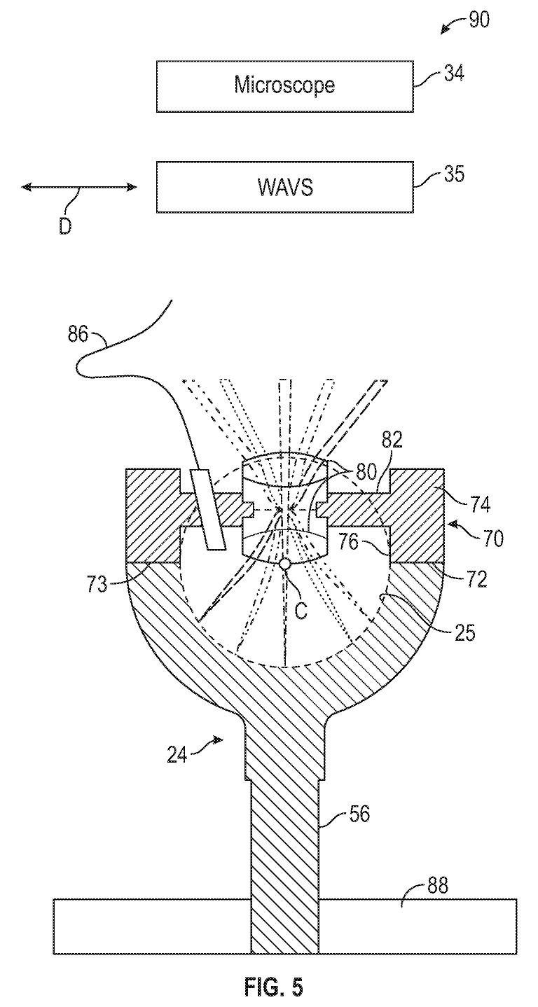

FIGS. 1-2 illustrate an example fabrication fixture 20 for positioning a metrology tool 24. The fabrication fixture 20 and metrology tool 24 are used in combination with a laser assembly 32 (FIG. 2) to create markings 26 at predetermined locations on a hemispherical surface 25 on the metrology tool 24. The fabrication fixture 20 includes a base 22 for supporting, a latitudinal positioning portion 28, and a rotational (longitudinal) positioning portion 30. The latitudinal positioning portion 28 and the rotational positioning portion 30 allow for the hemispherical surface 25 to be selectively positioned relative to the laser assembly 32 in a plurality of predetermined latitudinal and rotational positions. One feature of the fabrication fixture 20 is that it allows for the markings 26 to have an ultra-precise laser resolution on the hemispherical surface 25 of the metrology tool 24. Once the markings 26 are formed on the hemispherical surface 25, the metrology tool 24 is assembled with the lens assembly 70 (FIG. 5) to assess or benchmark optical capabilities of a WAVS 35 positioned relative to an ophthalmic microscope 34 as shown in FIG. 5 and discussed in greater detail below.

One feature of the latitudinal positioning portion 28 on the fabrication fixture 20 is to selectively vary a latitudinal intersectional point between laser beams L from the laser assembly 32 and the hemispherical surface 25. One feature of this disclosure is that the laser beams L pass through a center point C located at an equator of the hemispherical surface 25 as shown in FIG. 2 with varying positions of the latitudinal positioning portion 28 and the rotational positioning portion 30. This enables the laser beams L to have a perpendicular intersection with the hemispherical surface 25. The perpendicular intersection increases the precision of the markings 26 formed on the hemispherical surface 25 with the laser assembly 32 and therefore, the ability to assess or benchmark optical capabilities of the WAVS 35. When the laser assembly 32 forms the markings 26, the laser assembly 32 directs movement of a laser to ensure that the laser beams L pass through the center point C to maintain the near-perpendicular intersection with the hemispherical surface 25.

In the illustrated example, the latitudinal positioning portion 28 includes a pair of rails 42 that are coupled to the base 22 through a corresponding pair of projections 40 that extend upward from the base 22. As shown in FIGS. 1-2, the pair of projections 40 extend in a direction away from a base support surface 22B on the base 22. The base support surface 22Bis configured to engage a platform, such as a table, for supporting the fabrication fixture 20 to prevent movement of the metrology tool 24 while forming the markings 26 on the hemispherical surface 25.

In the illustrated example, each of the rails 42 at least partially define a slot 44 that follows an arcuate profile. In one example, the arcuate profile of the slot 44 includes a center of curvature located at the center point C of the hemispherical surface 25. This allows for the latitudinal positioning portion 28 to selectively position the point of intersection with the hemispherical surface 25 at different latitudes along the hemispherical surface 25 while maintaining the laser beams L to pass through the center point C. In this disclosure, measurements of latitude are with respect to the pole P and not the equator of the hemispherical surface 25. This allows the measurements of latitude to align with a field of view (FOV) outward from the pole P when assessing performance of the ophthalmic microscope 34 with the WAVS 35 shown in FIG. 5.

In the illustrated example, each of the rails 42 include latitude guide recesses 46 corresponding to a predetermined latitude on the hemispherical surface 25 for the laser beams L to engage the surface. A detent 48, such as a spring loaded detent, located in at least one of the projections 40 selectively engages corresponding latitude guide recesses 46 in the rails 42 to secure the latitudinal positioning portion 28 at a desired latitude for creating the markings with the laser assembly 32. Furthermore, the latitudinal positioning portion 28 may include a bearing 49, such as a needle roller bearing, coupled to each of the projections 40 about an axle 41 to ensure precise movement. This allows the center point C to remain at a constant location when the latitudinal positioning portion 28 is moved between each of the latitude guide recesses 46.

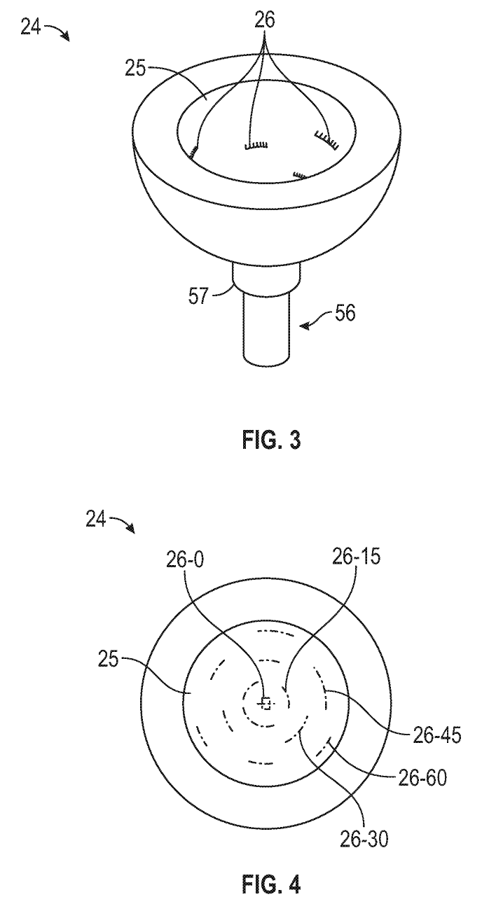

As shown in FIGS. 3-4, the markings 26 are positioned circumferentially around the hemispherical surface 25. In the illustrated example, the hemispherical surface 25 includes multiple sets of markings 26 located at each of the different circumferential positions at a given latitude. In one example, each set of the markings 26 includes markings 26 of different dimensions. In one example shown in FIG. 7, the markings 26 include standardized United States Air Force (USAF) 1951 Resolving Power Test Target feature geometry having a series of horizontal markings located adjacent to a series of vertical markings as shown in FIG. 7. With the markings 26 located at different latitudes and having different resolutions along each latitude, the optical performance of the WAVS 35 can be determined as discussed in greater detail below.

As shown in FIG. 4, the hemispherical surface 25 includes a first set of markings 26-0 located at zero degrees or adjacent to the pole P, a second set of markings 26-15 circumferentially spaced at fifteen degrees of latitude, a third set of markings 26-30 circumferentially spaced at thirty degrees of latitude, a fourth set of markings 26-45 circumferentially spaced at forty-five degrees of latitude, and a fifth set of markings 26-60 circumferentially spaced at sixty degrees of latitude. While a specific set of latitudes are given for the markings 26, the markings 26 can be located at different latitudes on the hemispherical surface 25.

One feature of the markings 26 at the predetermined locations, such as 26-0 through 26-60, is that the markings 26 can be used to compare optical performance of different optical devices, such as different WAVS 35 for the microscope 34. In one example, the hemispherical surface 25 can be anodized, such as with a black anodizing. The metrology tool 24 can be comprised of aluminum. When the markings 26 are formed into the hemispherical surface 25 after anodizing the metrology tool 24, a laser induced color change of the metrology tool material provides a greater contrast to the black anodized coating on the remainder of the hemispherical surface 25 to improve visualization of the markings 26.

As shown in FIGS. 1-2, the rotational positioning portion 30 includes a body 50 fixed relative to each of the rails 42 by fasteners 52. One feature of the rotational positioning portion 30 is that it maintains the laser beams L perpendicular to the hemispherical surface 25 at the point of contact. The rotational positioning portion 30 supports the metrology tool 24 to allow the metrology tool 24 to rotate about an axis of rotation R. In the illustrated example, the axis of rotation R intersects both the center point C and the pole P of the hemispherical surface 25. As the latitudinal positioning portion 28 moves relative to the base 22, the axis R of the metrology tool 24 continues to extend through the center point C and the pole P on the hemispherical surface 25.

The body 50 of the rotational positioning portion 30 includes a gear drive unit 54, such as a screw drive, which accepts a shaft 56 (or some other form of projection) extending from the metrology tool 24. In one example, the shaft 56 includes a shoulder 57 and is keyed relative to the gear drive unit 54 to allow the gear drive unit 54 to rotate the metrology tool 24. In the illustrated example, the gear drive unit 54 includes a rotary input knob 58 that causes the metrology tool 24 to rotate in a desired rotational direction about the axis of rotation R when rotated in one of a first rotational direction or a second rotational direction. The gear drive unit 54 can also include a lock 59 (such as a detent or other locking mechanism) that prevents the gear drive unit 54 from rotating. This allows the metrology tool 24 to remain fixed during when the markings 26 are formed into the hemispherical surface 25.

FIG. 5 illustrates an optical metrology tool assembly 90 for determining the optical performance of the WAVS 35 utilizing the metrology tool 24 once the markings are formed thereon as described above. In the illustrated example, the assembly 90 includes the microscope 34, the WAVS 35, a light source 86, and a lens assembly 70 attached to the metrology tool 24 supported by a stand 88. The assembly 90 is configured such that the microscope 34 can visualize the hemispherical surface 25 through the WAVS 35 using the light source 86. In one example, the light source 86 includes an endoilluminator / chandelier and the lens assembly may include an entry port on a top flat surface of the lens assembly 70 for insertion of the light source 86.

In the illustrated example, the lens assembly 70 includes a mating surface 73 in direct engagement with an attachment surface 72 located on a distal end of the metrology tool 24. The attachment surface 72 corresponds to an equatorial surface on the metrology tool 24 with a center corresponding to the center point C. The lens assembly 70 includes a cylindrical body portion 74 having an inner surface 76 that aligns with the hemispherical surface 25 on the metrology tool. In particular, a diameter defined by the inner surface 76 is twice a radius from the center point C to the hemispherical surface 25. One feature of the radius of the hemispherical surface 25 is that a circle inscribed within the hemispherical surface 25 closely approximates the dimensions of an average eye. This allows the metrology tool 24 to simulate the visualization surface for retinal procedures that would be performed on the eye of a patient with the microscope 34 and WAVS 35.

The lens assembly 70 also includes at least one lens 80 or more lenses. In one example, a first lens 80 is located adjacent to the center point C and a second lens 80 is located within an aperture defined by a lens support 82 located radially inward from the inner surface 76. One feature of the lens assembly 70 is to closely approximate the total optical power characteristics within a patient’s eye. This allows the optical performance determined for the WAVS 35 to closely approximate the performance expected when viewing the patient's eye.

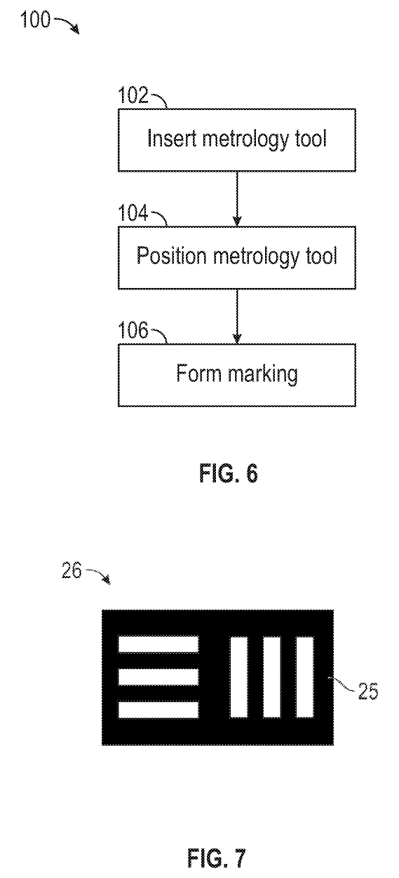

FIG. 6 is a flow diagram of an example method 100 of operating the fabrication fixture 20 to form the markings on the metrology tool 24 for use with the assembly 90 of FIG. 5. The method 100 begins at block 102 (“Insert Metrology Tool”) with inserting the metrology tool 24 into the fabrication fixture 20. With the metrology tool 24 is inserted into the fabrication fixture 20, the method 100 proceeds to block 104.

At block 104 (“Position Metrology Tool”), the metrology tool 24 is positioned into one of a multitude of predetermined rotational and latitudinal positions. The metrology tool 24 is positioned into each of these positions through utilizing the rotational positioning portion 30 and the latitudinal positioning portion 28 on the fabrication fixture 20. In particular, when the latitudinal positioning portion 28 is positioned at one of the predetermined latitudes with the detent 48 engaging one of the recesses 46, the rotational positioning portion 30 can rotate the metrology tool 24 about the rotational axis R. This allows the laser assembly 32 to form the marks 26 at a fixed latitude that are circumferentially spaced from each other. With the metrology tool positioned, the method 100 proceeds to block 106.

At block 106 (“Form Marking”), the laser assembly 32 is utilized to form the markings 26 to the hemispherical surface 25. Because the laser assembly 32 is utilized to form the markings 26, the markings 26 are recessed into or produce a color change in the hemispherical surface 25. As shown in FIG. 7, each marking 26 includes a vertical and horizontal portion. At different circumferential positions on the metrology tool at a given latitude, a set of markings 26 can be formed as a group with each marking 26 in the set having a different resolution, such as varying a size dimension of the marking 26 as shown in FIGS. 4, 7. This allows for the optical performance of the WAVS 35 to be established by determining which marking 26 in the set at the given latitude has both the horizontal and vertical components of the mark 26 resolved.

The terms “a” and “an” do not denote a limitation of quantity, but rather denote the presence of at least one of the referenced items. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in a suitable manner in the various aspects.

While the above disclosure has been described with reference to exemplary embodiments, it will be understood by those skilled in the art that various changes may be made, and equivalents may be substituted for elements thereof without departing from its scope. In addition, many modifications may be made to adapt a particular situation or material to the teachings of the disclosure without departing from the scope thereof. Therefore, it is intended that the present disclosure is not limited to the particular embodiments disclosed but will include embodiments falling within the scope thereof.

What is claimed is:

1. A fabrication fixture assembly, comprising:
a base including at least one projection;
a latitudinal positioning portion having at least one rail defining an arcuate slot extending therethrough, wherein the arcuate slot follows a radius of curvature and the at least one projection is coupled to the latitudinal positioning portion through the at least one rail; and
a rotational positioning portion attached to the at least one rail and moveable with the latitudinal positioning portion, wherein the rotational positioning portion is configured to accept a metrology tool and selectively position the metrology tool in one of a plurality of rotational positions.

2. The fabrication fixture assembly of claim 1, including the metrology tool attached to the rotational positioning portion for rotating the metrology tool between a plurality of rotational positions, wherein a portion of the metrology tool defines a hemispherical surface.

3. The fabrication fixture assembly of claim 2, wherein the at least one projection attached relative to the base includes a bearing.

4. The fabrication fixture assembly of claim 3, including a center point at a center of a radius of curvature of the hemispherical surface.

5. The fabrication fixture assembly of claim 1, including a detent configured to engage one of a plurality of recesses on at least one rail to secure the at least one rail in one of a plurality of positions relative to the base.

6. The fabrication fixture assembly of claim 5, wherein the rotational positioning portion is fixed relative to the at least one rail.

7. The fabrication fixture assembly of claim 2, wherein the metrology tool includes a plurality of markings at a plurality of latitudes and rotational positions along a hemispherical surface.

8. The fabrication fixture assembly of claim 7, wherein the plurality of marking includes a set of markings with each marking in the set having a different resolution.

9. The fabrication fixture assembly of claim 2, wherein the rotational positioning portion includes a gear drive unit and a detent for securing the metrology tool into one of a plurality of rotational positions.

10. The fabrication fixture assembly of claim 2, wherein the metrology tool includes a projection configured to engage the rotational positioning portion of the fabrication fixture.

11. A method of operating a fabrication fixture to form markings on a metrology tool, the method comprising:
inserting a metrology tool into the fabrication fixture, wherein the metrology tool includes a hemispherical surface having a center point and a pole;
positioning the metrology tool into one of a plurality of predetermined rotational and latitudinal positions, wherein the metrology tool is positioned into each of the plurality of predetermined rotational and latitudinal positions with a rotational positioning portion and a latitudinal positioning portion on the fabrication fixture and the rotational positioning portion is configured to rotate the metrology tool about a rotational axis extending through the center point and the pole; and
forming at least one marking at each of the plurality of predetermined rotational and latitudinal positions on the hemispherical surface of the metrology tool.

12. The method of claim 11, wherein the at least one marking includes a set of markings with each marking in the set of markings having a different resolution.

13. The method of claim 12, wherein the at least one marking includes a plurality of horizontal marks and a plurality of vertical marks.

14. The method of claim 11, wherein forming the at least one marking includes directing a laser beam through the center point and into engagement with the hemispherical surface.

15. The method of claim 11, wherein the center point of the hemispherical surface remains in a fixed location for each of the plurality of predetermined rotational and latitudinal positions.

16. An optical metrology tool assembly, comprising:
a metrology tool including a hemispherical surface having a center point and a pole, wherein a shaft extends from the metrology tool on an opposite side of the metrology tool from the hemispherical surface;
an optical assembly located adjacent to an attachment surface on the metrology tool, wherein the optical assembly includes:
a cylindrical body portion having a diameter equal to twice a radial distance from the center point to the hemispherical surface, wherein the cylindrical body includes a mating surface for engaging a distal end of the metrology tool and the cylindrical body portion defines a central opening; and
at least one lens is located within the central opening and fixed relative to the cylindrical body portion.

17. The optical metrology tool assembly of claim 16, wherein the optical assembly includes at least one entry port on a top flat surface for insertion of endoilluminator / chandelier illumination sources.

18. The optical metrology tool assembly of claim 17, including a plurality of markings located at at least a plurality of latitudes on the hemispherical surface.

19. The optical metrology tool assembly of claim 18, wherein the plurality of marking at each of the latitudes include a set of markings having different resolutions.

20. The optical metrology tool assembly of claim 18, wherein the hemispherical surface is anodized and the plurality of markings are either recessed via laser material removal into the hemispherical surface or laser marked surface color changes without material removal.
